(19) United States
(12) Patent Application Publication
(10) Pub. No.: US 2025/0374612 A1
(43) Pub. Date: Dec. 4, 2025

(54) SEMICONDUCTOR DEVICE INCLUDING A FIELD EFFECT TRANSISTOR AND METHOD OF MANUFACTURING THE SAME

(71) Applicant: SAMSUNG ELECTRONICS CO., LTD., SUWON-SI (KR)

(72) Inventors: JUNG-HYUN OH, Suwon-si (KR); HOON CHANG, Suwon-si (KR); JUNGKYUNG KIM, Suwon-si (KR); HEEJUNG KIM, Suwon-si (KR); JAEHONG JEONG, Suwon-si (KR)

(21) Appl. No.: 19/013,297

(22) Filed: Jan. 8, 2025

(30) Foreign Application Priority Data
May 31, 2024 (KR) 10-2024-0071744

(51) Int. Cl. H10D 30/68; H10D 30/01

(52) U.S. Cl. CPC H10D 30/6892; H10D 30/0411; H10D 30/683

(57) ABSTRACT

A semiconductor device includes: a substrate including a first active pattern and a second active pattern that are spaced apart from each other in a first direction; first doped regions disposed on the first active pattern and spaced apart from each other in a second direction that intersects the first direction; lower doped regions interposed between the first doped regions and spaced apart from each other in the second direction; and an erase gate disposed on the first active pattern and the lower doped regions, wherein the first doped regions and the lower doped regions have a same conductivity type as each other, and wherein the first doped regions include a material that is different from a material of the lower doped regions.

### CROSS-REFERENCE TO RELATED APPLICATION

This U.S. non-provisional patent application claims priority under 35 U.S.C. § 119 to Korean Patent Application No. 10-2024-0071744, filed on May 31, 2024, in the Korean Intellectual Property Office, the disclosure of which is incorporated by reference herein in its entirety.

### TECHNICAL FIELD

The present inventive concept relates to a semiconductor device and a method of manufacturing the same, and more particularly, to a semiconductor device including a field effect transistor and a method of manufacturing the same.

### DISCUSSION OF THE RELATED ART

Typically, a semiconductor device may include an integrated circuit having, for example, metal-oxide-semiconductor field effect transistors (MOSFET). As size and design for the semiconductor device continue to become smaller, MOSFETs continue to be scaled down. The scale-down of the MOSFET may cause characteristics of certain semiconductor devices to degrade. Accordingly, research has been conducted to overcome the limitations resulting from increased integration of the semiconductor device and to manufacture the semiconductor device with increased performance.

### SUMMARY

According to embodiments of the present inventive concept, a semiconductor device includes: a substrate including a first active pattern and a second active pattern that are spaced apart from each other in a first direction; first doped regions disposed on the first active pattern and spaced apart from each other in a second direction that intersects the first direction; lower doped regions interposed between the first doped regions and spaced apart from each other in the second direction; and an erase gate disposed on the first active pattern and the lower doped regions, wherein the first doped regions and the lower doped regions have a same conductivity type as each other, and wherein the first doped regions include a material that is different from a material of the lower doped regions.

According to embodiments of the present inventive concept, a semiconductor device includes: a substrate including a first active pattern and a second active pattern that are spaced apart from each other in a first direction; an erase gate disposed on the first active pattern; a selection gate and a control gate disposed on the second active pattern; and first doped regions disposed on the first active pattern and spaced apart from each other by a first distance in a second direction that intersects the first direction, wherein the erase gate is disposed between the first doped regions, and wherein a width of the erase gate in the second direction is smaller than the first distance.

According to embodiments of the present inventive concept, a semiconductor device includes: a substrate including a first active pattern and a second active pattern that are spaced apart from each other in a first direction; a first well disposed on the first active pattern; a second well disposed on the second active pattern; first doped regions disposed in the first well and spaced apart from each other in a second direction that intersects the first direction; a second doped region, a third doped region, and a fourth doped region disposed in the second well; lower doped regions interposed between the first doped regions and spaced apart from each other in the second direction; an erase gate disposed on the lower doped regions; and a selection gate and a control gate disposed on the second active pattern, wherein the first doped regions are spaced apart from each other by a first distance, wherein a width of the erase gate in the second direction is smaller than the first distance, wherein the second to fourth doped regions have a same conductivity type as each other, and wherein the first doped regions have a conductivity type that is different from a conductivity type of the second to fourth doped regions.

### BRIEF DESCRIPTION OF THE DRAWINGS

The above and other aspects of the present inventive concept will become more apparent by describing in detail embodiments thereof, with reference to the accompanying drawings, in which:

FIG. 1 is a plan view of a semiconductor device according to embodiments of the present inventive concept.

FIG. 2A is a cross-sectional view taken along line A-A′ in FIG. 1.

FIG. 2B is a cross-sectional view taken along line B-B′ in FIG. 1.

FIGS. 3, 4A, 4B, 5, 6A, 6B, 7, 8A, 8B, 9, 10A and 10B are diagrams illustrating a method of manufacturing a semiconductor device according to embodiments of the present inventive concept. FIGS. 3, 5, 7, and 9 are plan views illustrating a method of manufacturing a semiconductor device according to embodiments of the present inventive concept. FIGS. 4A, 6A, 8A, and 10A are cross-sectional views taken along line A-A′ of FIGS. 3, 4, 5, 7, and 9, respectively. FIGS. 4B, 6B, 8B and 10B are cross-sectional views taken along line B-B′ of FIGS. 3, 5, 7 and 9 respectively.

### DETAILED DESCRIPTION OF THE EMBODIMENTS

Hereinafter, embodiments of the present inventive concept will be described with reference to the accompanying drawings. The same reference numerals may refer to the same elements throughout the specification and drawings, and thus, their descriptions that are redundant may be omitted. In the following description, singular expressions may include plural expressions unless the context clearly dictates otherwise.

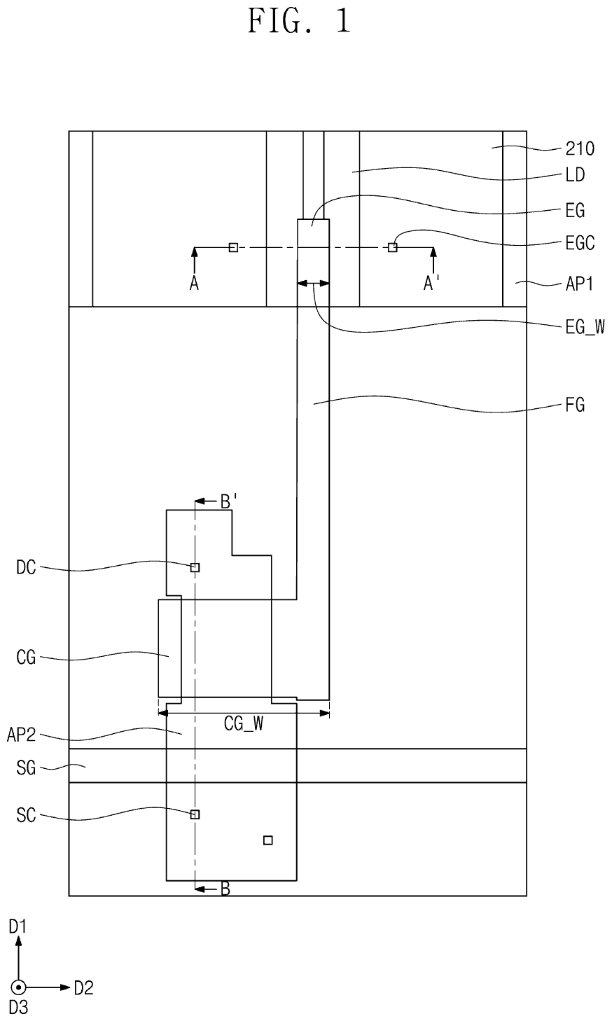

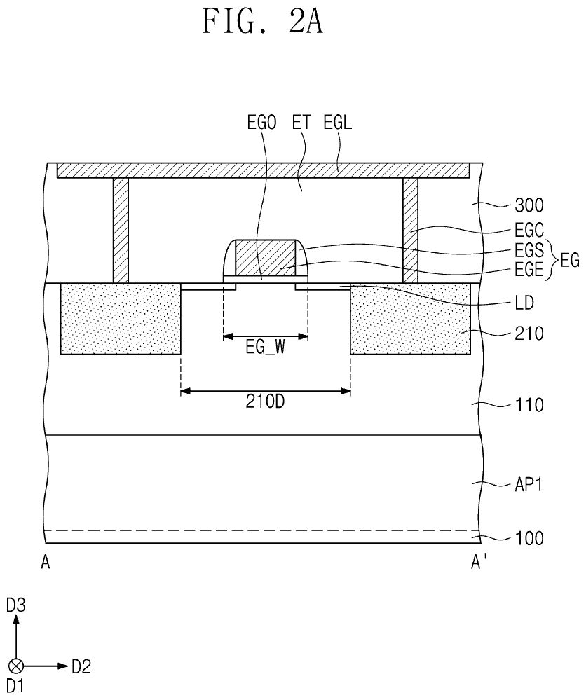

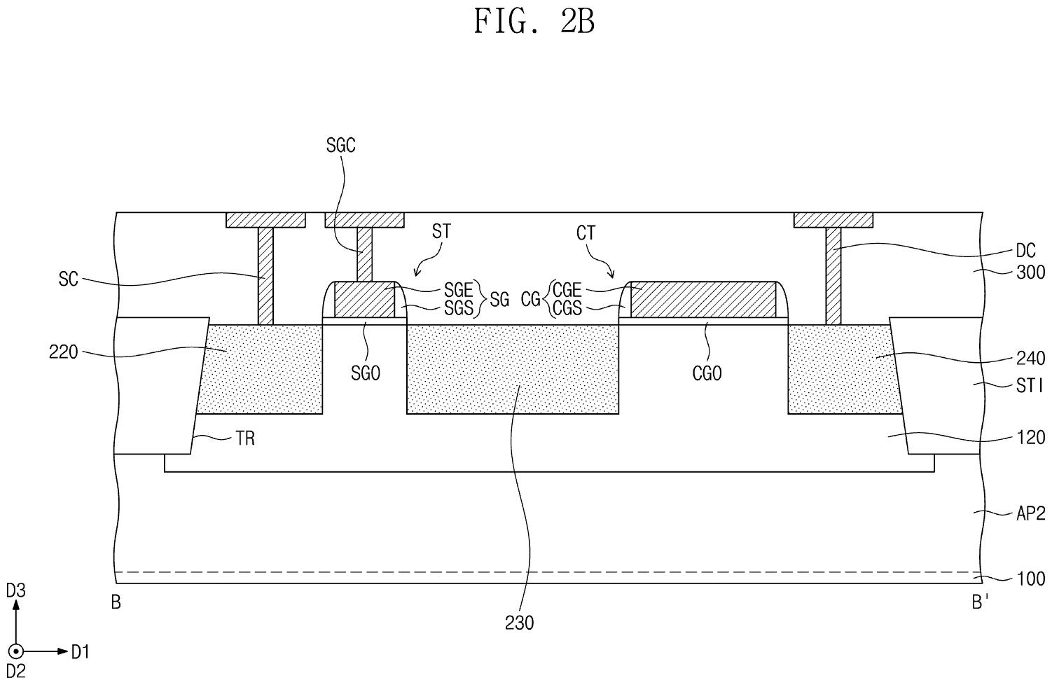

FIG. 1 is a plan view of a semiconductor device according to embodiments of the present inventive concept. FIG. 2A is a cross-sectional view taken along line A-A′ in FIG. 1. FIG. 2B is a cross-sectional view taken along line B-B′in FIG. 1.

Referring to FIGS. 1, 2A, and 2B, a substrate 100 may include a first active pattern AP1 and a second active pattern AP2. The first active pattern AP1 and the second active pattern AP2 may be spaced apart from each other in a first direction D1. The first active pattern AP1 and the second active pattern AP2 may be defined by a trench TR that is formed on the substrate 100. The first active pattern AP1 and the second active pattern AP1 and AP2 may be portions of the substrate 100 and may be portions that protrude in a third direction D3 that is substantially perpendicular to an upper surface of the substrate 100.

A device isolation layer STI may be provided on the substrate 100. The device isolation layer STI may fill a trench TR. The device isolation layer STI may include, for example, a silicon oxide layer.

A first well 110 may be disposed in the first active pattern AP1. A second well 120 may be disposed in the second active pattern AP2. The first well 110 and the second well 120 may have different conductivity types from each other. For example, the first well 110 may be p-type, and the second well 120 may be n-type.

Lower doped regions LD may be disposed in the first well 110. The lower doped regions LD may be spaced apart from each other in a second direction D2 that intersects the first direction D1. The lower doped regions LD may be doped with a first dopant at a first doping concentration. The first dopant may be an n-type dopant and, for example, may include phosphorus.

First doped regions 210 may be disposed in the first well 110. The first doped regions 210 may be spaced apart from each other by a first distance 210D in the second direction D2. The lower doped regions LD may be disposed between the first doped regions 210. For example, a pair of lower doped regions LD may be disposed between a pair of first doped regions 210. For example, the first doped regions 210 may be doped with a second dopant at a second doping concentration, and may include the first dopant and the second dopant. The first dopant and the second dopant may be different materials from each other. For example, the second dopant may be an n-type dopant and, for example, may include at least one of arsenic (As) and/or antimony (Sb). The second doping concentration of the second dopant in the first doped regions 210 may be higher than the first doping concentration of the first dopant in the lower doped regions LD.

For example, the first doped regions 210 may have the same conductivity type as the lower doped regions LD and may include a material that is different from the lower doped regions LD. For example, the first doped regions 210 may include the first dopant and the second dopant, and the lower doped regions LD may include the first dopant and might not include the second dopant. As an example, the first doped regions 210 may include phosphorus (P) and may further include at least one of arsenic (As) and/or antimony (Sb). The lower doped regions LD may include phosphorus (P) and might not include arsenic (As) and antimony (Sb).

A second doped region 220, a third doped region 230, and a fourth doped region 240 may be disposed on the second active pattern AP2. The second to fourth doped regions 220, 230, and 240 may have the same conductivity type as each other. The second to fourth doped regions 220, 230, and 240 may have a different conductivity type from that of the first doped regions 210. Each of the first doped regions 210 may be, for example, an n-type doped region, and each of the second to fourth doped regions 220, 230, and 240 may be, for example, a p-type doped region.

An erase transistor ET may be disposed on the first well 110. The erase transistor ET may include an erase gate EG. The erase gate EG may be disposed on the lower doped regions LD. A width EG_W of the erase gate EG in the second direction D2 may be smaller than the first distance 210D. The erase gate EG may include an erase gate electrode EGE and an erase gate spacer EGS that is disposed on sides of the erase gate electrode EGE. For example, the erase gate spacer EGS may be disposed on opposing sides of the erase gate electrode EGE. For example, the erase gate electrode EGE may include polysilicon. For example, the erase gate spacer EGS may include silicon oxide. The erase gate EG might not overlap the first doped regions 210 when viewed in a plan view. For example, the erase gate EG might not vertically overlap the first doped regions 210. Each of the first doped regions 210 may be spaced apart from the erase gate spacer EGS in the second direction D2. For example, the lower doped regions LD may be disposed between the erase gate EG and the first doped regions 210.

The erase gate EG may overlap at least a portion of the lower doped regions LD when viewed in a plan view. For example, the erase gate EG may vertically overlap at least a portion of the lower doped regions LD. The erase gate spacer EGS may vertically overlap at least a portion of the lower doped regions LD. Each of the lower doped regions LD may protrude further in the second direction D2 than the erase gate EG and may protrude toward the first doped regions 210. Each of the lower doped regions LD may extend in the second direction D2, while being disposed under the erase gate EG, and may be connected to an adjacent first doped region among the first doped regions 210.

An erase gate insulating layer EGO may be disposed under the erase gate electrode EGE and may be disposed on the lower doped regions LD. The erase gate insulating layer EGO may be interposed between the erase gate EG and the first well 110 and between the erase gate EG and the lower doped regions LD. For example, the erase gate insulating layer EGO may include silicon oxide.

A selection transistor ST and a control transistor CT may be disposed on the second well 120. The selection transistor ST may include a selection gate SG, and the control transistor CT may include a control gate CG. The selection gate CG may be disposed between the second doped region 220 and the third doped region 230. The selection gate SG may include a selection gate electrode SGE and a selection gate spacer SGS disposed on sides of the selection gate electrode SGE. For example, the selection gate spacer SGS may be disposed on opposing sides of the selection gate electrode SGE.

The control gate CG may be disposed between the third doped region 230 and the fourth doped region 240. The control gate CG may include a selection gate electrode CGE and a control gate spacer CGS disposed on sides of the control gate electrode CGE. For example, the control gate spacer CGS may be disposed on opposing sides of the control gate electrode CGE. A width CG_W of the control gate CG in the second direction D2 may be greater than the width EG_W of the erase gate EG in the second direction D2.

A selection gate insulating layer SGO may be disposed under the selection gate SG. A control gate insulating layer CGO may be disposed below the control gate CG. For example, the selection gate insulating layer SGO and the control gate insulating layer CGO may include silicon oxide.

A floating gate FG may extend in the first direction DI to connect the erase gate EG and the control gate CG to each other. The floating gate FG may include a portion of the control gate CG and a portion of the erase gate EG. The floating gate FG may include a portion of the erase gate electrode EGE and a portion of the control gate electrode CGE.

An insulating layer 300 may be disposed on the first well 110 and the second well 120. The insulating layer 300 may cover the erase gate EG, the selection gate SG, the control gate CG, and the floating gate FG.

Control conductive contacts EGC may be disposed on the first doped regions 210 and may penetrate the insulating layer 300. The control conductive contacts EGC may be spaced apart from each other in the second direction D2. The control conductive contacts EGC may be connected to each other through a control conductive line EGL that extends in the second direction D2.

A selection gate contact SGC may be disposed on the selection gate electrode SGE and may be disposed in the insulating layer 300. The selection transistor ST may be turned on or off through the selection gate contact SGC. In the turn-on state, the selection transistor ST may classify data as 0 or 1 depending on the program or erase state of the control transistor CT.

A source conductive contact SC may be disposed on the second doped region 220 and in the insulating layer 300. A drain conductive contact DC may be disposed on the fourth doped region 240 and in the insulating layer 300. The drain conductive contact DC may read data by measuring the amount of charged or discharged charge of the floating gate FG.

The semiconductor device according to embodiments of the present inventive concept may program or erase data by charging or discharging charge in the floating gate FG.

For example, in the case of a recording operation, a voltage may be applied to the control conductive contacts EGC and the source conductive contact SC to record data through the Fowler-Nordheim (FN) tunneling method. Tunneling may occur under the control transistor CT due to a potential difference between the control conductive contacts EGC and the source conductive contact SC. Electrons may be injected into the floating gate FG when the potentials of the control conductive contacts EGC and the source conductive contact SC correspond to positive voltages. For example, the semiconductor device according to embodiments of the present inventive concept may record data by injecting electrons into the floating gate FG through the control transistor CT.

In the case of an erase operation, a voltage is applied to the control conductive contacts EGC and the source conductive contact SC to erase data through the FN tunneling method. Tunneling may occur under the control transistor CT due to a potential difference between the control conductive contacts EGC and the source conductive contact SC. The floating gate FG may emit electrons when the potentials of the control conductive contact EGC and the source conductive contact SC correspond to a negative voltage. For example, the semiconductor device according to embodiments of the present inventive concept may erase data by emitting electrons from the floating gate FG through the control transistor CT.

Furthermore, in the semiconductor device according to embodiments of the present inventive concept, at least a portion of the lower doped regions LD may overlap the erase gate EG when viewed in a plan view. Additionally, the width CG_W of the control gate CG in the second direction D2 may be greater than the width EG_W of the erase gate EG in the second direction D2. As a result, the semiconductor device having a high coupling ratio between a capacitor corresponding to the control gate CG and a capacitor corresponding to the erase gate

EG may be provided. Therefore, the semiconductor device with increased erase operation efficiency may be provided.

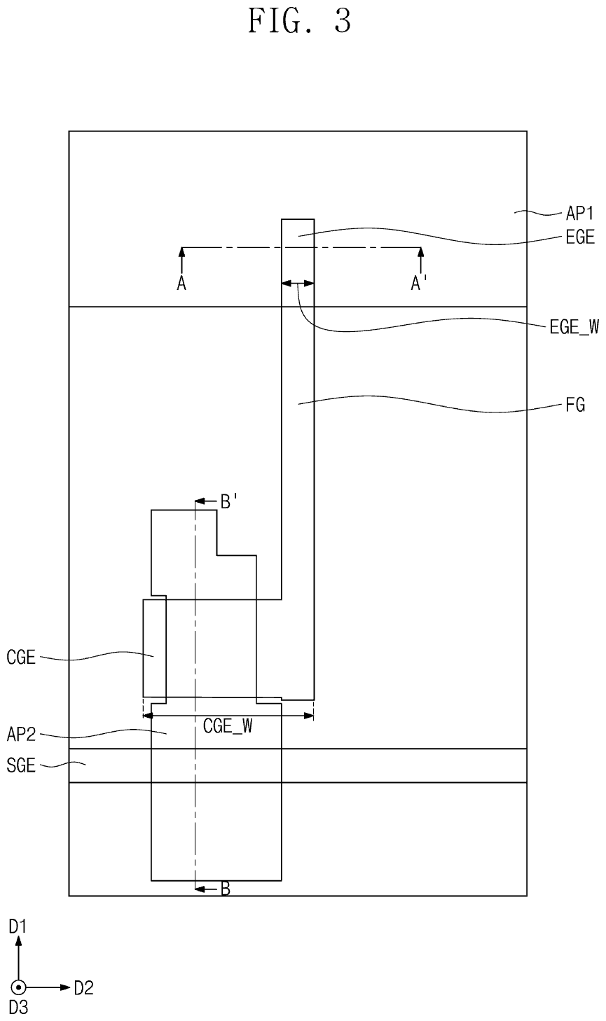

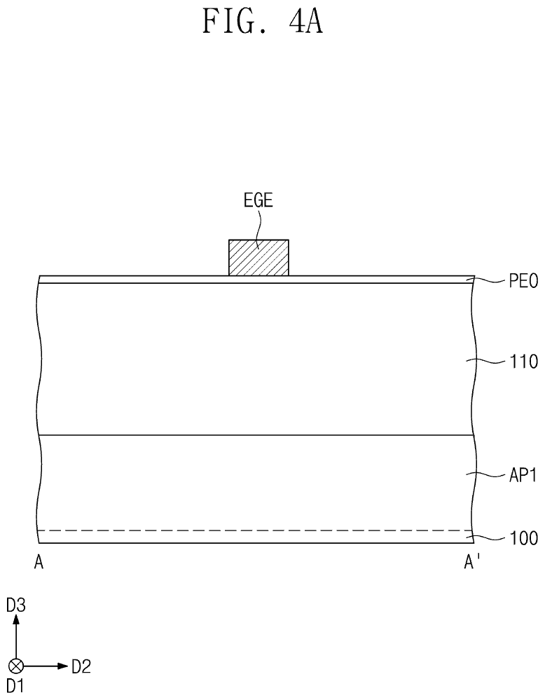

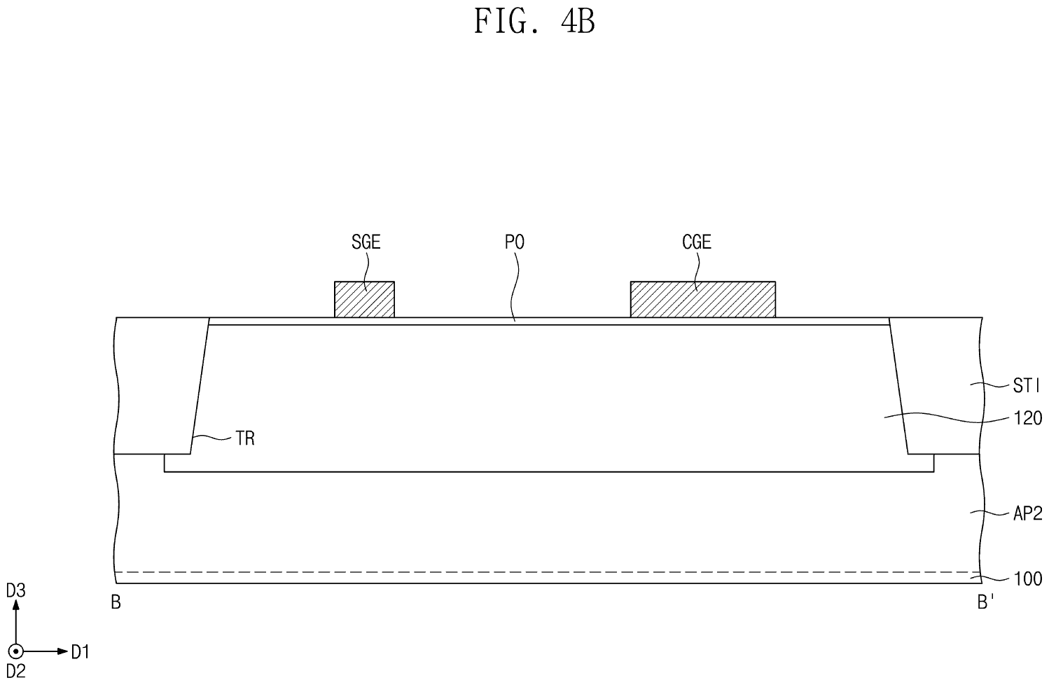

FIGS. 3, 4A, 4B, 5, 6A, 6B, 7, 8A, 8B, 9, 10A and 10B are diagrams illustrating a method of manufacturing a semiconductor device according to embodiments of the present inventive concept. FIGS. 3, 5, 7, and 9 are plan views illustrating a method of manufacturing a semiconductor device according to embodiments of the present inventive concept. FIGS. 4A, 6A, 8A, and 10A are cross-sectional views taken along line A-A′ of FIGS. 3, 4, 5, 7, and 9, respectively. FIGS. 4B, 6B, 8B and 10B are cross-sectional views taken along line B-B′ of FIGS. 3, 5, 7 and 9 respectively.

Hereinafter, to simplify the description, descriptions of technical features that overlap with those described with reference to FIGS. 1 to 2B will be omitted or briefly discussed.

Referring to FIGS. 3, 4A, and 4B, a substrate 100 including a first active pattern AP1 and a second active pattern AP2 may be provided. The first active pattern AP1 and the second active pattern AP2 may be spaced apart from each other in a first direction D1 that extends parallel to an upper surface of the substrate. A trench TR defining the first active pattern AP1 and the second active pattern AP2 may be formed. For example, forming the trench TR may include forming a mask pattern on the substrate 100 and patterning the substrate 100 by using the mask patterns as an etch mask. A device isolation layer STI may be formed to fill the trench TR.

A first well 110 may be formed in the first active pattern AP1. For example, the first well 110 may include in-situ injecting impurities (e.g., boron, gallium, or indium) that causes the first active pattern API to be a p-type.

A second well 120 may be formed in the second active pattern AP2. For example, the second well 120 may include in-situ injecting impurities (e.g., phosphorus, arsenic, or antimony) that causes the second active pattern AP2 to be an n-type.

A preliminary erase gate insulating layer PEO may be formed on the first active pattern AP1. For example, forming the preliminary erase gate insulating layer PEO may include a chemical vapor deposition (CVD) process. A preliminary gate insulating layer PEO may be formed on the second active pattern AP2. Forming the preliminary gate insulating layer PEO may include, for example, a chemical vapor deposition (CVD) process.

An erase gate electrode EGE may be formed on the first active pattern AP1. The erase gate electrode EGE may be formed on the first well 110 and may be formed on the preliminary erase gate insulating layer PEO. A selection gate electrode SGE and a control gate electrode CGE may be formed on the second well 120. The selection gate electrode SGE and the control gate electrode CGE may be formed to be spaced apart from each other in the first direction D1. A width of the control gate electrode CGE_W in a second direction D2 may be greater than a width of the erase gate electrode EGE_W in the second direction D2. The floating gate FG may extend in the first direction D1 to connect the control gate electrode CGE and the erase gate electrode EGE to each other. A floating gate FGE may include a portion of the erase gate electrode EGE and a portion of the control gate electrode CGE.

For example, forming the erase gate electrode EGE, the selection gate electrode SGE, the control gate electrode CGE, and the floating gate FG may include, for example, forming a conductive material on the first well 110 and the second well 120, forming a gate mask pattern on the conductive material, and etching the conductive material by using the gate mask pattern as an etch mask.

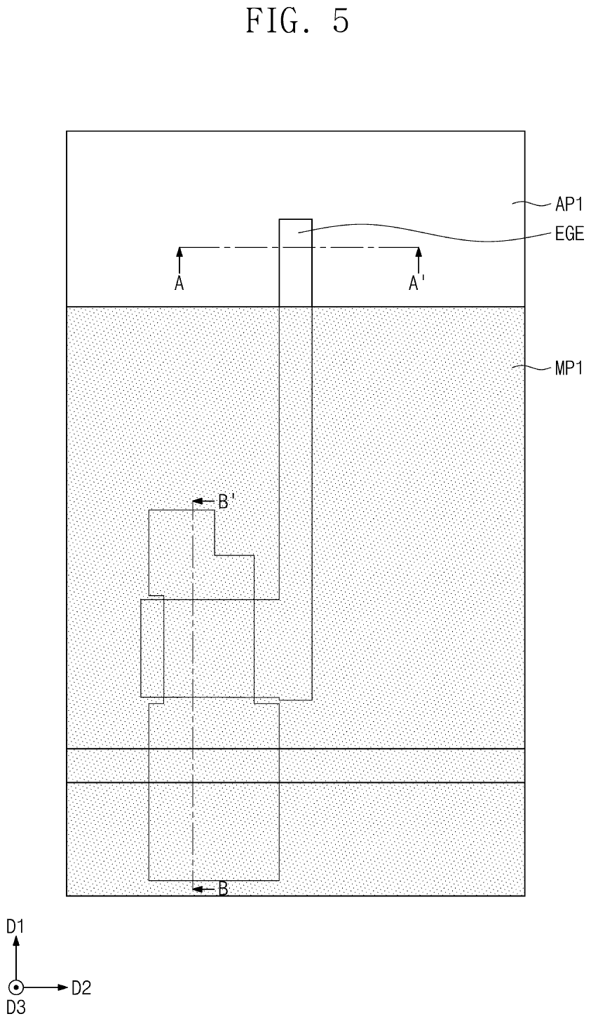

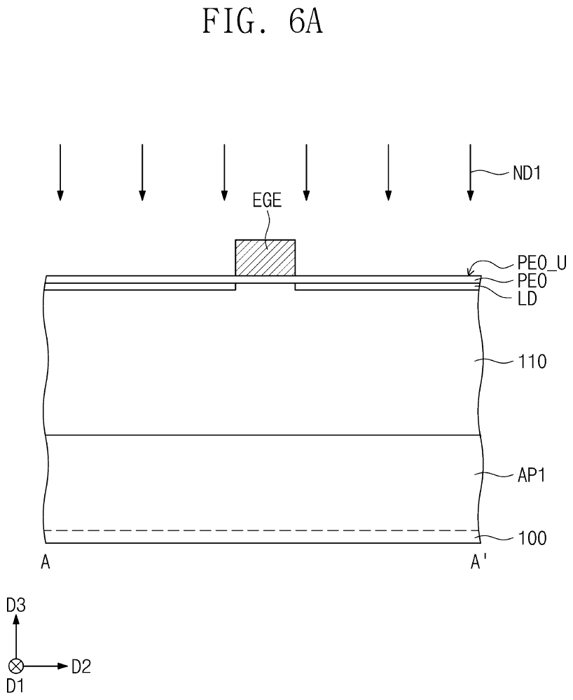

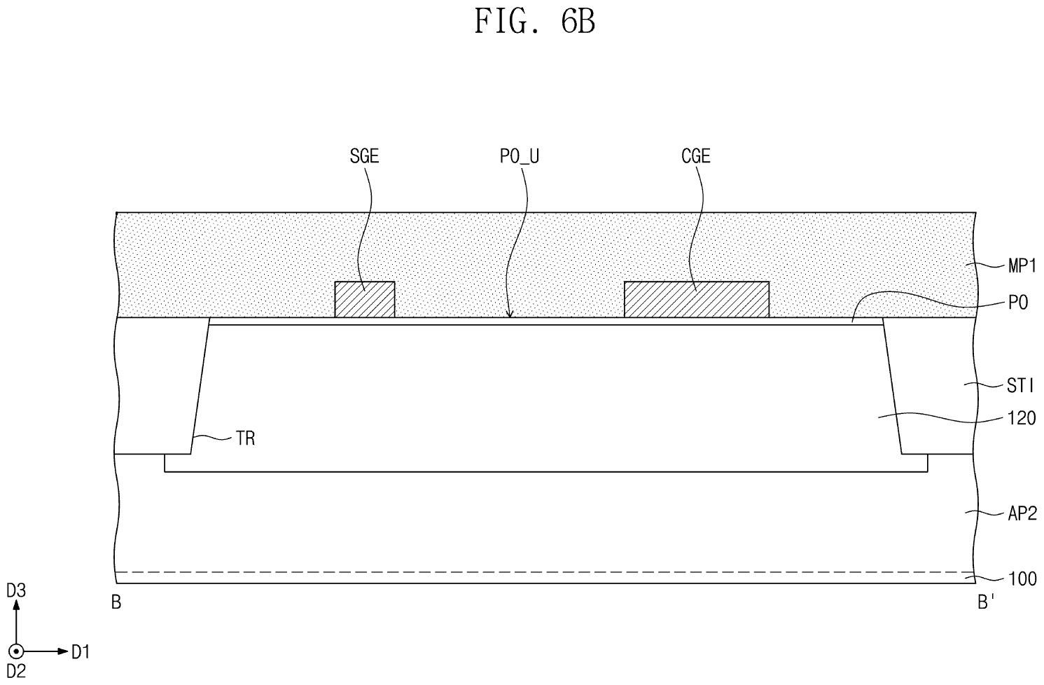

Referring to FIGS. 5, 6A, and 6B, a first mask pattern MP1 may be formed on the second well 120. The first mask pattern MP1 may expose an upper surface PEO_U of the preliminary erase gate insulating layer PEO and the erase gate electrode EGE. The first mask pattern MP1 may cover the second well 120, the selection gate electrode SGE, and the control gate electrode CGE. For example, the first mask pattern MP1 may cover upper surfaces of the second well 120, the selection gate electrode SGE, and the control gate electrode CGE.

Lower doped regions LD may be formed in the first well 110. The lower doped regions LD may be formed under the preliminary erase gate insulating layer PEO. For example, forming the lower doped regions LD may include in-situ injecting the first dopant ND1 into the first well 110 at a first doping concentration. For example, the first dopant ND1 may include phosphorus. The lower doped regions LD may be spaced apart from each other in the second direction D2 that intersects the first direction D1. The lower doped regions LD may be spaced apart from each other with the erase gate electrode EGE interposed therebetween. After the lower doped regions LD are formed, the first mask pattern MP1 may be removed.

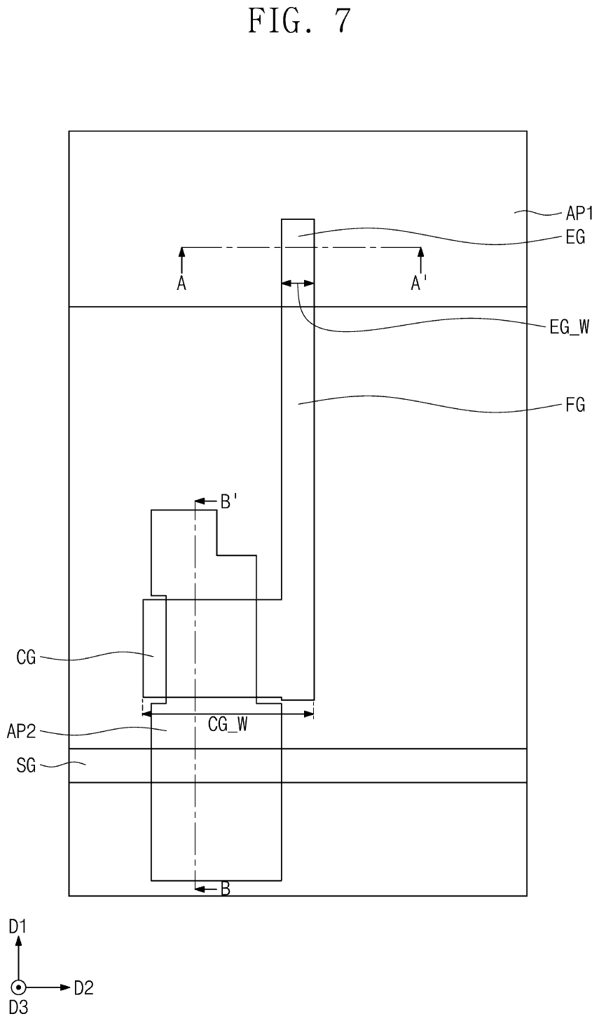

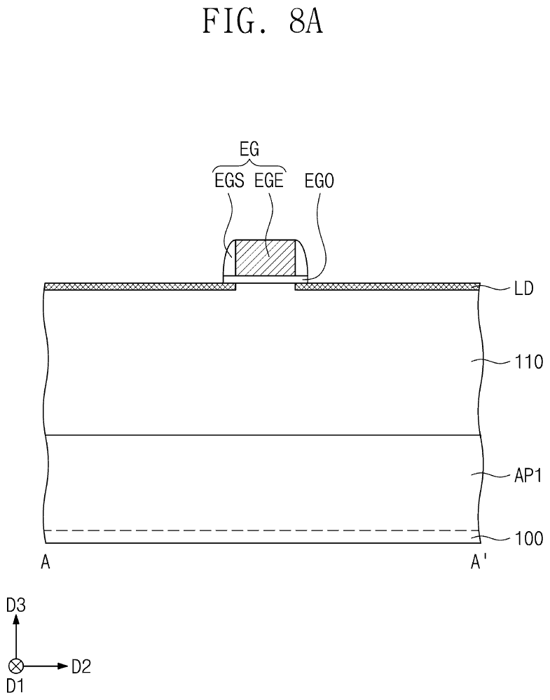

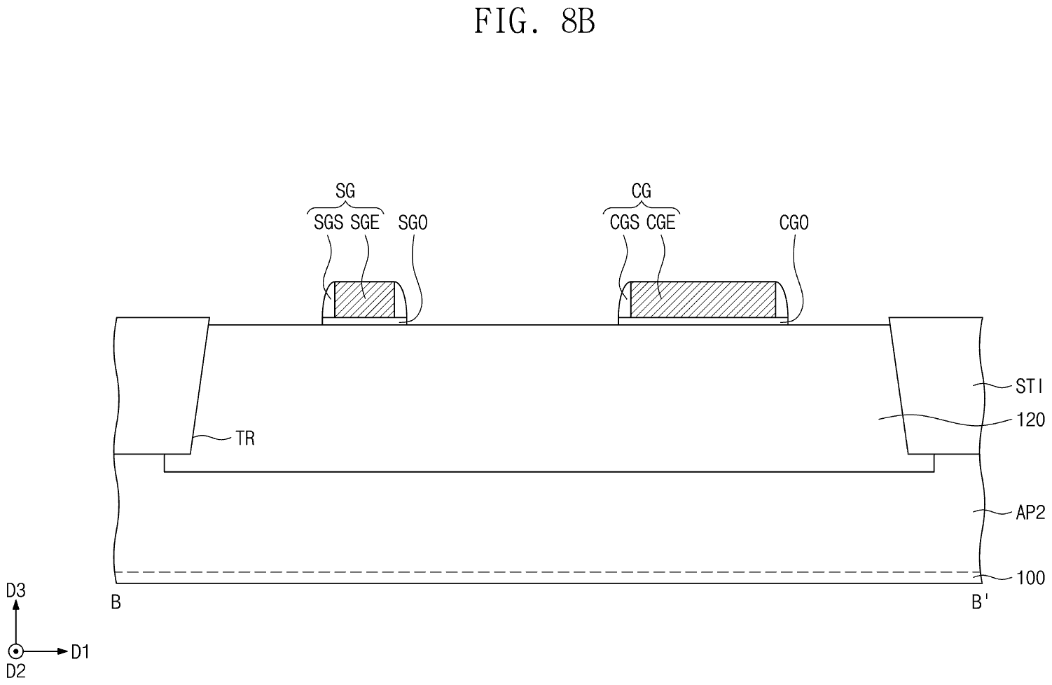

Referring to FIGS. 7, 8A, and 8B, an erase gate insulating layer EGO, a selection gate insulating layer SGO, and a control gate insulating layer CGO may be formed. Forming the erase gate insulating layer EGO may include, for example, etching the preliminary erase gate insulating layer PEO that is formed on both sides of the erase gate electrode EGE. For example, the erase gate electrode EGE may act as an etching mask. Forming the selection gate insulating layer SGO and the control gate insulating layer CGO may include, for example, etching the preliminary gate insulating layer PO that is formed on both sides of the selection gate electrode SGE and both sides of the control gate electrode CGE. For example, each of the selection gate electrode SGE and the control gate electrode CGE may act as an etching mask.

Erasing gate spacers EGS may be formed on sides of the erase gate electrode EGE. For example, forming the erase gate spacer EGS may include forming a first preliminary spacer layer covering the erase gate electrode EGE and etching the preliminary spacer layer. For example, an erase gate EG may be formed by forming the erase gate spacer EGS. The erase gate EG may include the erase gate electrode EGE and the erase gate spacer EGS. At least a portion of the lower doped regions LD may overlap the erase gate EG when viewed in a plan view. The lower doped regions LD may protrude further in the second direction D2 than the erase gate EG. For example, the lower doped regions LD may extend beyond the erase gate EG in the second direction D2 when viewed in a plan view.

Selection gate spacers SGS may be formed on sides of the selection gate electrode CG, and control gate spacers CGS may be formed on sides of the control gate electrode CG. For example, forming the selection gate spacer SGS may include forming a second preliminary spacer layer covering the selection gate electrode SGE and etching the second preliminary spacer layer. For example, a selection gate SG may be formed by forming the selection gate spacer SGS. The selection gate SG may include the selection gate electrode SGE and the selection gate spacer SGS. For example, forming the control gate spacer CGS may include forming the second preliminary spacer layer covering the control gate electrode CGE and etching the second preliminary spacer layer. For example, a control gate CG may be formed by forming the control gate spacer CGS. The control gate CG may include the control gate electrode CGE and the control gate spacer CGS. A width CG_W of the control gate CG in the second direction D2 may be greater than a width EG_W of the erase gate EG in the second direction D2.

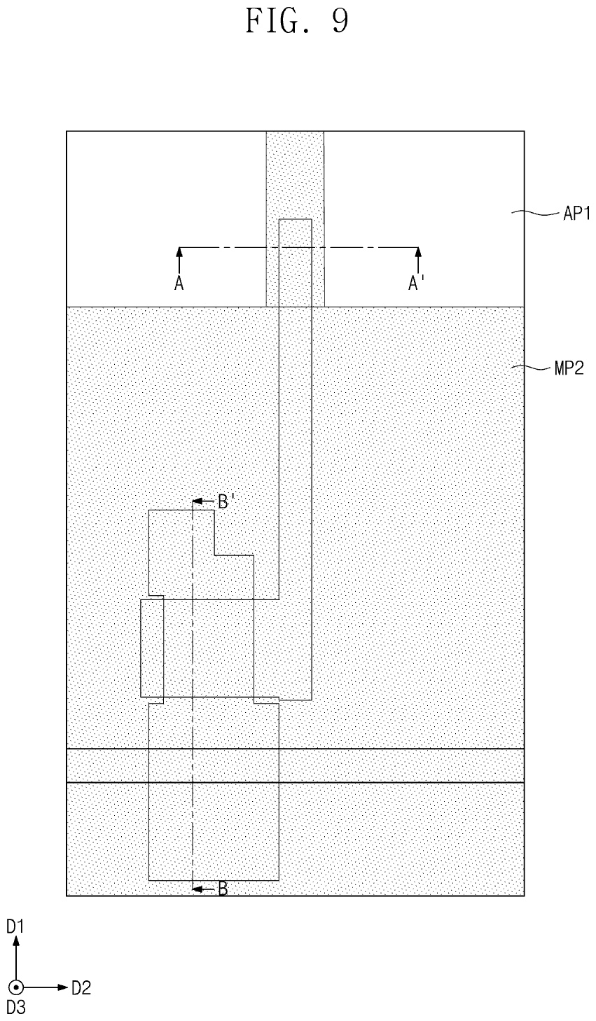

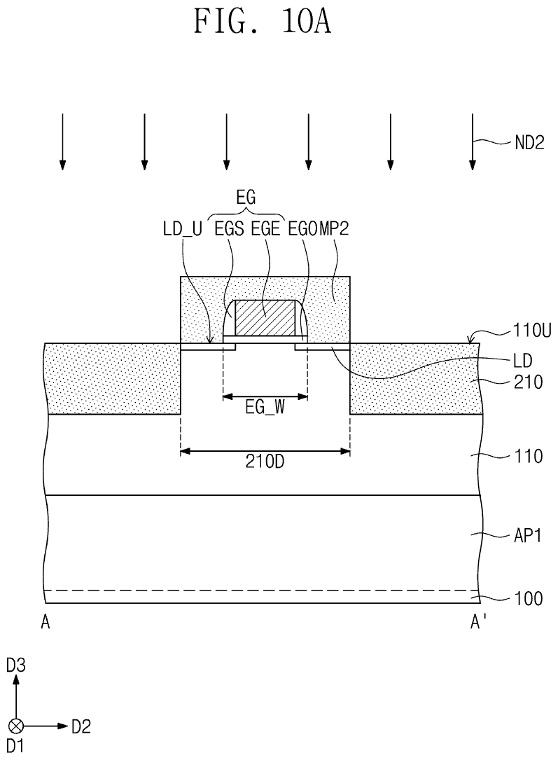

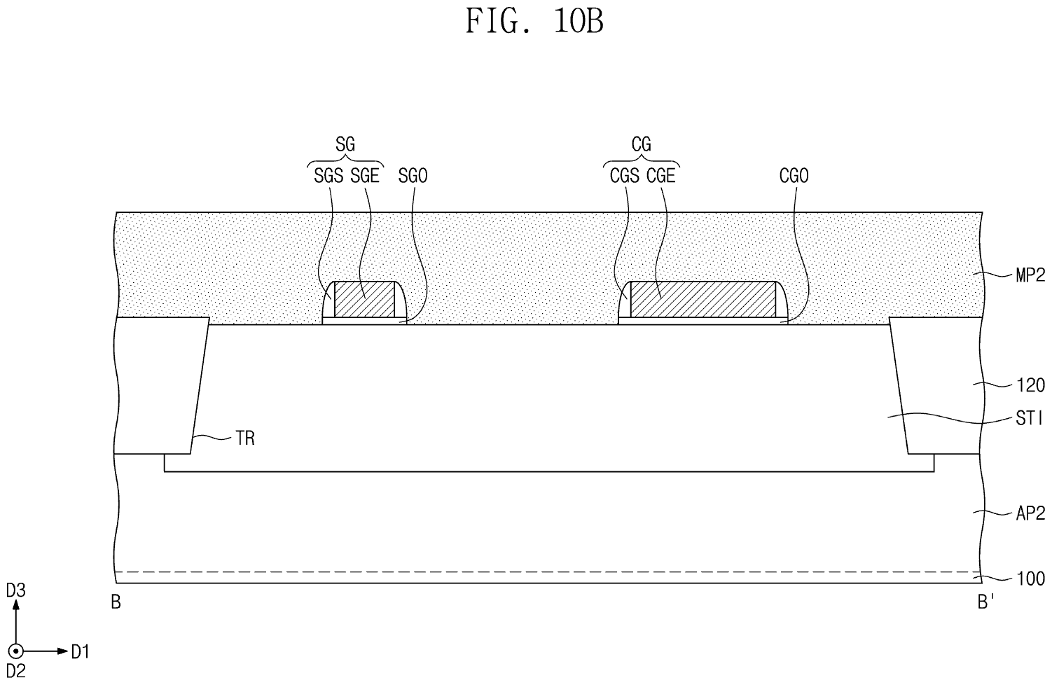

Referring to FIGS. 9, 10A and 10B, a second mask pattern MP2 may be formed on the first well 110 and the second well 120. The second mask pattern MP2 may cover an upper surface 120U of the second well 120, the selection gate SG, and the control gate CG.

The second mask pattern MP2 may cover the erase gate EG and an upper surface LD_U of the lower doped regions LD. For example, the second mask pattern MP2 may completely cover the erase gate electrode EGE, the erase gate spacer EGS, and the lower doped regions LD. The second mask pattern MP2 may expose a portion of the upper surface 110U of the first well 110.

First doped regions 210 may be formed in the first well 110. For example, forming the first doped regions 210 may include in-situ injecting a second dopant into the first well 110 at a second doping concentration. The first doped regions 210 and the lower doped regions LD may have the same conductivity type as each other.

The second dopant ND2 may include a different material from that of the first dopant ND1. For example, the second dopant ND2 may include one of arsenic or antimony. The second doping concentration may be higher than the first doping concentration.

The first doped regions 210 may be spaced apart from each other in the second direction D2. The first doped regions 210 may be spaced apart from each other by a first distance 210D in the second direction D2 that intersects the first direction D1. The first distance 210D may be greater than the width EG_W of the erase gate EG in the second direction D2. After the first doped regions 210 are formed, the second mask pattern MP2 may be removed.

According to embodiments of the present inventive concept, in the doping process to form the first doped regions 210, the erase gate EG may be protected by the second mask pattern MP2. Accordingly, the erase gate EG might not be damaged. Therefore, the semiconductor device with increased reliability and increased electrical performance may be provided.

Referring again to FIGS. 1, 2A, and 2B, a second doped region 220, a third doped region 230, and a fourth doped region 240 may be formed in the second well 120. For example, forming the second to fourth doped regions 220, 230, and 240 may include forming a third mask pattern on an upper surface of the first active pattern AP1 and in-situ injecting impurities (e.g., boron, gallium, or indium) that causes the second well 120 to be p-type. The semiconductor device according to embodiments of the present inventive concept are not limited to the manufacturing order of forming the first doped regions 210 and then the second to fourth doped regions 220, 230, and 240, in that sequential order. Alternatively, the first doped regions 210 may be formed after the second to fourth doped regions 220, 230, and 240 are formed.

An insulating layer 300 may be formed on the first well 110 and the second well 120. The insulating layer 300 may cover the erase gate EG, the selection gate SG, the control gate CG, and the floating gate FG.

Control conductive contacts EGC may be formed on the first doped regions 210 and may be formed in the insulating layer 300. The control conductive contacts EGC may be spaced apart from each other in the second direction D2. The control conductive contacts EGC may be connected to each other through a control conductive line EGL extending in the second direction D2. The control conductive line EGL may be formed in the insulating layer 300 and/or on an upper surface of the insulating layer 300. For example, the control conductive line EGL may be formed in a groove of the insulating layer 300. A selection gate contact SGC may be formed on the selection gate electrode SGE and may be formed in the insulating layer 300.

A source conductive contact SC may be formed on the second doped region 220 and may be formed in the insulating layer 300. A drain conductive contact DC may be formed on the fourth doped region 240 and may be formed in the insulating layer 300.

According to embodiments of the present inventive concept, the erase gate EG and the first doped region 210 might not overlap each other. The first doped region 210 may be an N-type doped region. As the first doped region 210 and the erase gate EG do not overlap each other, the erase gate EG may be prevented from being damaged by the doping process of the first doped region. Accordingly, the reliability and electrical performance of the semiconductor device may be increased.

Furthermore, at least some of the lower doped regions LD may overlap the erase gate EG when viewed in a plan view. Accordingly, the semiconductor device having the high coupling ratio between the capacitor corresponding to the control gate CG and the capacitor corresponding to the erase gate EG may be provided. Therefore, the semiconductor device with increased erase operation efficiency may be provided.

While the present invention has been described with reference to embodiments thereof, it will be understood by those of ordinary skill in the art that various changes in form and details may be made thereto without departing from the spirit and scope of the present invention.

What is claimed is:

1. A semiconductor device comprising:
a substrate including a first active pattern and a second active pattern that are spaced apart from each other in a first direction;
first doped regions disposed on the first active pattern and spaced apart from each other in a second direction that intersects the first direction;
lower doped regions interposed between the first doped regions and spaced apart from each other in the second direction; and
an erase gate disposed on the first active pattern and the lower doped regions,
wherein the first doped regions and the lower doped regions have a same conductivity type as each other, and
wherein the first doped regions include a material that is different from a material of the lower doped regions.

2. The semiconductor device of claim 1, wherein the lower doped regions include a first dopant,
wherein the first doped regions include a second dopant that is different from the first dopant, and
wherein the lower doped regions do not include the second dopant.

3. The semiconductor device of claim 2, wherein the lower regions are doped with the first dopant at a first doping concentration,
wherein the first doped regions are doped with the first dopant at the first doping concentration and the second dopant at the second doping concentration, and
wherein the second doping concentration of the second dopant of the first doped regions is higher than the first doping concentration of the first dopant of the lower doped regions.

4. The semiconductor device of claim 1, wherein the first doped regions are spaced apart from each other by a first distance in the second direction, and the erase gate is disposed between the first doped regions,
wherein a width of the erase gate in the second direction is smaller than the first distance.

5. The semiconductor device of claim 1, wherein at least a portion of the lower doped region overlaps the erase gate.

6. The semiconductor device of claim 1, wherein the erase gate includes an erase gate electrode and erase gate spacers that are disposed on sides of the erase gate electrode, and
wherein each of the first doped regions is spaced apart from the erase gate spacer in the second direction.

7. The semiconductor device of claim 1, further comprising:
a first well disposed on the first active pattern;
a second well disposed on the second active pattern; and
a second doped region, a third doped region, and a fourth doped region disposed in the second well,
wherein the first doped regions are disposed in the first well,
wherein the second to fourth doped regions are spaced apart from each other in the first direction in the second well,
wherein the second to fourth doped regions have the same conductivity type as each other, and
wherein the first doped regions have a conductivity type that is different from a conductivity type of the second to fourth doped regions.

8. The semiconductor device of claim 7, further comprising:
control conductive contacts disposed on the first doped regions, respectively;
a source conductive contact disposed on the second doped region; and
a drain conductive contact disposed on the fourth doped region,
wherein the control conductive contacts are connected to each other through a control conductive line.

9. The semiconductor device of claim 1, further comprising:
a selection gate and a control gate disposed on the second active pattern; and
a floating gate extending in the first direction and connecting the control gate and the erase gate to each other.

10. The semiconductor device of claim 1, wherein the first doped regions do not overlap the erase gate.

11. A semiconductor device comprising:
a substrate including a first active pattern and a second active pattern that are spaced apart from each other in a first direction;
an erase gate disposed on the first active pattern;
a selection gate and a control gate disposed on the second active pattern; and
first doped regions disposed on the first active pattern and spaced apart from each other by a first distance in a second direction that intersects the first direction,
wherein the erase gate is disposed between the first doped regions, and
wherein a width of the erase gate in the second direction is smaller than the first distance.

12. The semiconductor device of claim 11, further comprising lower doped regions interposed between the first doped regions,
wherein the lower doped regions are spaced apart from each other in the second direction, and
wherein the erase gate is disposed on the lower doped regions.

13. The semiconductor device of claim 12, wherein the lower doped region and the first doped region include different materials from each other.

14. The semiconductor device of claim 12, wherein the erase gate includes an erase gate electrode and erase gate spacers that are disposed on sides of the erase gate electrode, and
wherein at least a portion of the lower doped regions overlaps the erase gate spacer.

15. The semiconductor device of claim 11, further comprising control conductive contacts disposed on each of the first doped regions,
wherein the control conductive contacts are connected to each other through a control conductive line.

16. The semiconductor device of claim 11, wherein a width of the control gate in the second direction is greater than a width of the erase gate in the second direction.

17. A semiconductor device comprising:
a substrate including a first active pattern and a second active pattern that are spaced apart from each other in a first direction;
a first well disposed on the first active pattern;
a second well disposed on the second active pattern;
first doped regions disposed in the first well and spaced apart from each other in a second direction that intersects the first direction;
a second doped region, a third doped region, and a fourth doped region disposed in the second well;
lower doped regions interposed between the first doped regions and spaced apart from each other in the second direction;
an erase gate disposed on the lower doped regions; and
a selection gate and a control gate disposed on the second active pattern,
wherein the first doped regions are spaced apart from each other by a first distance,
wherein a width of the erase gate in the second direction is smaller than the first distance,
wherein the second to fourth doped regions have a same conductivity type as each other, and
wherein the first doped regions have a conductivity type that is different from a conductivity type of the second to fourth doped regions.

18. The semiconductor device of claim 17, further comprising a selection gate contact disposed on the selection gate.

19. The semiconductor device of claim 17, wherein the first doped regions include a material that is different from a material of the lower doped regions.

20. The semiconductor device of claim 17, wherein at least a portion of the lower doped region overlaps the erase gate.
